(19) United States
(12) Patent Application Publication
(10) Pub. No.: US 2025/0085729 A1
(43) Pub. Date: Mar. 13, 2025

(54) Power Distribution Control System

(71) Applicant: Textron eAviation Inc., Providence, RI (US)

(72) Inventors: Brett Jacob Bergman, Wichita, KS (US); Kyle Austin Fanning, Wichita, KS (US)

(21) Appl. No.: 18/828,331

(22) Filed: Sep. 9, 2024

Related U.S. Application Data
(60) Provisional application No. 63/581,430, filed on Sep. 8, 2023.

(51) Int. Cl. G05F 1/46; H03K 19/20

(52) U.S. Cl. CPC G05F 1/46; H03K 19/20

(57) ABSTRACT

A method of controlling a power distribution system comprising an electronic controller in data communication with a first message converter and a second message converter, a logic circuit in data communication with the first and second message converters, and a switching device in data communication with the logic circuit is disclosed. The method includes sending a first message from the controller to the first message converter and sending a second, dissimilar, message from the controller to the second message converter. The method further includes generating a first command signal via the first message converter and generating a second command signal via the second message converter. The method further requires comparing the first command signal to the second command signal via the logic circuit, generating a final command signal based on the result of the comparison, and operating the switching device via the final command signal.

### CROSS-REFERENCE TO RELATED APPLICATIONS

This application claims the benefit of U.S. Provisional Patent Application No. 63/581,430, filed Sep. 8, 2023, the entire contents thereof are herein incorporated by reference.

### BACKGROUND

### 1. Field

The disclosure relates generally to the field of electrical power. More specifically, the disclosure relates to electrical power distribution control systems.

### 2. Related Art

Systems and methods for controlling the distribution of electrical power are generally known in the art. For example, U.S. Pat. No. 7,868,487 to Scharnick et al. describes a power distribution system having an intermediate control module providing two redundant control signals which are compared to ensure a change in state is acceptable. U.S. Pat. No. 11,476,061 to Raciti et al. discloses a power distribution system having a controller configured to put the system in a safe state when a fault is detected, and utilizes sensing signals as inputs to the controller to issue commands to the system. U.S. Patent Application Publication No. 2007/0076333 to Battani et al. discloses a power distribution system in which the state of the integrated contactors is verified, and if one or both of the contactors is determined to be in an abnormal condition, the system does not apply/distribute power. U.S. Patent Application Publication No. 2011/0222200 to Fuller et al. discloses a power distribution system with a solid-state power controller (SSPC) with an integrated solid-state switching device (SSSD); wherein an “off” signal is issued to the SSPC when receiving a command to turn “on” so it can verify that the SSPC is off before moving forward with the “on” command. The system of Fuller can also determine the state of the contactors using current/voltage sensing signals. U.S. Patent Application Publication No. 2016/0336754 to Radulescu et al. describes an aircraft power distribution system. Radulescu describes an SSPC and a system where power is supplied to two buses, wherein the power is further controlled using power bus controllers and monitored using powered bus controllers and monitored using bus monitors. The Radulescu system also includes integrated fault detection.

### SUMMARY

The following presents a simplified summary of the invention in order to provide a basic understanding of some aspects of the invention. This summary is not an extensive overview of the invention. It is not intended to identify critical elements of the invention or to delineate the scope of the invention. Its sole purpose is to present some concepts of the invention in a simplified form as a prelude to the more detailed description that is presented elsewhere herein.

In an embodiment, a method of controlling a power distribution system comprising an electronic controller connected to and in data communication with a first message converter and a second message converter, a logic circuit in data communication with the first and second message converters, and a switching device in data communication with the logic circuit includes sending a first message from the controller to the first message converter. The method includes sending a second message from the controller to the second message converter, with the second message being dissimilar to the first message. The method includes generating a first command signal and outputting the first command signal from the first message converter. The method further requires generating a second command signal and outputting the second command signal from the second message converter. The method also includes comparing the first command signal to the second command signal via the logic circuit, generating a final command signal based on the result of the comparison, and operating the switching device via the final command signal.

In another embodiment, a power distribution control system includes an electronic controller, a first message converter connected to and in data communication with the controller, and a second message converter connected to and in data communication with the controller. The power distribution control system also includes a switching device, a logic circuit in data communication with the first message converter, the second message converter, and the switching device. The electronic controller is configured to send a first message to the first message converter and send a second message to the second message converter, with the second message being dissimilar to the first message. The first message converter is configured to generate a first command signal upon receiving a message from the controller, and the second message converter is configured to generate a second command signal upon receiving a message from the controller.

In another embodiment, a power distribution control system has an electronic controller and a plurality of message converters, with each message converter being connected to and in data communication with the electronic controller. The system includes a plurality of switching devices and a plurality of logic circuits, with each logic circuit being in data communication with the plurality of message converters and the plurality of switching devices. The electronic controller is configured to generate a plurality of messages and send a message of said plurality of messages to each message converter of the plurality of message converters, and at least one message of the plurality of messages is dissimilar from another message of the plurality of messages. Each message converter of the plurality of message converters is configured to generate a command signal upon receiving a message from the controller.

### BRIEF DESCRIPTION OF THE DRAWING FIGURES

Illustrative embodiments of the present disclosure are described in detail below with reference to the attached drawing figures, wherein:

FIG. 1 illustrates a schematic view of an embodiment of a power distribution control system;

FIG. 2 illustrates a schematic view of message validation circuit forming part of the power distribution control system of FIG. 1; and

FIG. 3 illustrates a schematic view of another embodiment of a message validation circuit forming part of another embodiment of a power distribution control system.

### DETAILED DESCRIPTION

The following detailed description references the accompanying drawings that illustrate specific embodiments in which the invention can be practiced. The embodiments are intended to describe aspects of the invention in sufficient detail to enable those skilled in the art to practice the invention. Other embodiments can be utilized, and changes can be made without departing from the scope of the invention. The following detailed description is, therefore, not to be taken in a limiting sense. The scope of the invention is defined only by the appended claims, along with the full scope of the equivalents to which such claims are entitled.

In this description, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the technology can include a variety of combinations and/or integrations of the embodiments described herein.

Electrical power distribution systems are common in the vehicle industry, and are increasingly more integral to a vehicle's overall operation and safety as electric vehicles (including cars, trucks, and/or aircraft) become more prevalent. Existing systems and methods for controlling the distribution of electrical power typically include having a primary controller directly commanding individual contactors and/or relays in said power distribution system. In this configuration, any failure of the controller may result in partial or complete loss of power and/or control of all equipment, potentially causing an accident or other catastrophic damage. An existing alternative approach is to include multiple identical redundant controllers such that if one controller fails the other(s) continue to operate normally and take control to keep the relevant equipment powered. However, with identical controllers a common failure mode may potentially result in partial or complete loss of power or control of all equipment, again potentially causing an accident or other catastrophic damage. To avoid or at least significantly reduce the risk of a multiple-failure scenario, it may be advantageous to use multiple dissimilar controllers. With dissimilar controllers a common failure mode cannot exist due to the inherent dissimilarity. However, in some applications (such as aviation) it may be undesirable to have multiple dissimilar controllers because of increased cost and/or weight.

In an embodiment, a power distribution system for use in vehicles including, but not limited to, electric aircraft and/or fly-by-wire aircraft is contained in a housing. The power distribution system includes a power distribution control system 100 configured to monitor and operate the power distribution system in response to inputs from a vehicle operator. The power distribution control system 100 includes at least one controller 102 in data communication with one or more switching devices 104, such as contactors and/or relays, and each switching device 104 may include designated driving circuitry where appropriate. In the illustrated embodiments, the power distribution control system is shown with two or three switching devices 104; however, in other embodiments there may be any number of switching devices employed, without departing from the scope of the invention.

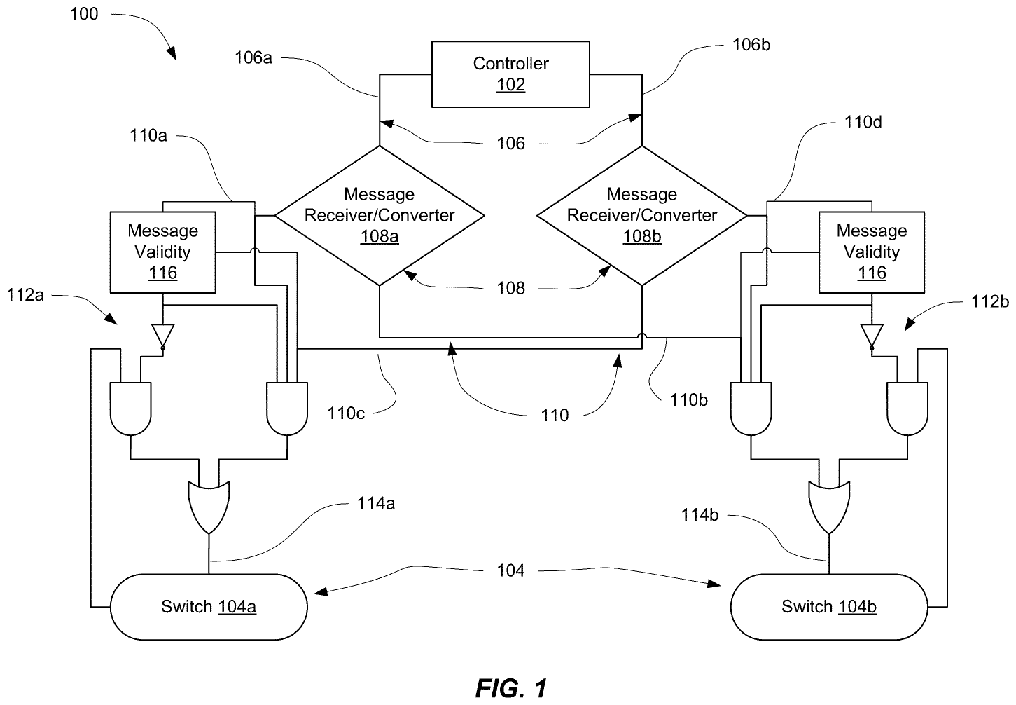

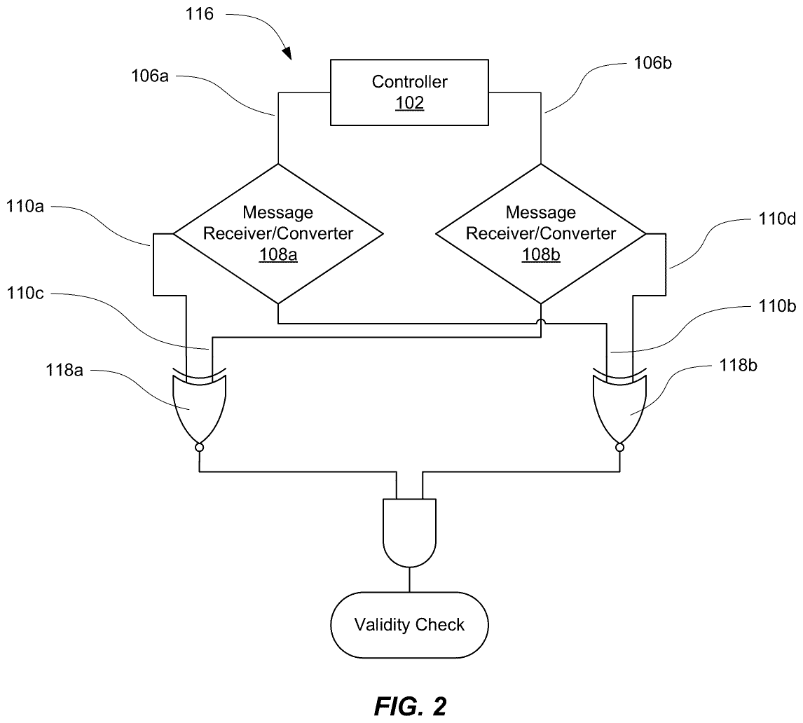

FIGS. 1 and 2 show various aspects of the power distribution control system 100. In response to an input from an operator or a signal sent by other electronic systems on the aircraft, the controller 102 sends a first and a second message 106a and 106b, respectively, to a first and second message converter 108a and 108b, respectively. The messages 106a and 106b may be sent over a databus network, using discrete controls, or by other methods now known or later developed. The message converters 108a and 108b may alternatively be referred to as message receivers in other applications or embodiments. The first message converter 108a takes the first message 106a and maps this message into a first command signal 110a and a second command signal 110b. The first command signal is intended for a first switching device 104a and the second command signal 110b is intended for a second switching device 104b. The first message converter 108a is connected to and in data communication with the first switching device 104a via a first logic circuit 112a and is similarly connected to and in data communication with the second switching device 104b via a second logic circuit 112b.

Similarly, the second message converter 108b takes the second controller message 106b and maps this message into a third command signal 110c and a fourth command signal 110d. Because the first message 106 and the second message 106b are dissimilar, the message converters 108a and 108b, respectively, use dissimilar mappings to generate the control signals 110a-110d. The third command signal 110c is intended for the first switching device 104a, while the fourth command signal 110d is intended for the second switching device 104b. Like the first message converter 108a, the second message converter 108b is connected to and in data communication with the first switching device 104a via a first logic circuit 112a and is similarly connected to and in data communication with the second switching device 104b via a second logic circuit 112b.

The logic circuits 112a and 112b may take any number of forms using simple discrete controls and logic gates, or may include or form part of a databus or databus network. In some embodiments, at least a portion of the logic circuits 112a and 112b may include and/or be referred to as a comparator. In the illustrated embodiment, the logic circuit validates the command signals (as shown in FIG. 2) and if the command signals are valid and the two command signals are identical, a final command signal 114a or 114b is passed to the respective switching device 104a or 104b. For example, if command signals 110a and 110c are found to be valid and are identical, then final command signal 114a will be passed to the switching device 104a, and the switch will change state. If command signals 110a and 110c are found to be dissimilar and/or invalid, then the final command signal 114a is not passed to the switching device 104a, and the state of the switching device does not change. In some embodiments, the messages 106a and 106b and/or the message converters 108a and 108b may be constructed in such a way that a null message does not map to a valid command, as might happen from a loss of power to the controller or other undesirable circumstance. If the controller 102 were to fail, the mapping may either hold last valid message or send invalid commands 110a-110d which would be prevented from erroneously operating the switching devices 104a, 104b, and the switching devices 104a, 104b would continue to hold their last known state. Existing power distribution control systems are generally configured such that upon controller or other component failure, the switching device(s) 104 are left open, resulting in a potentially dangerous lack of power and/or control for a vehicle operator.

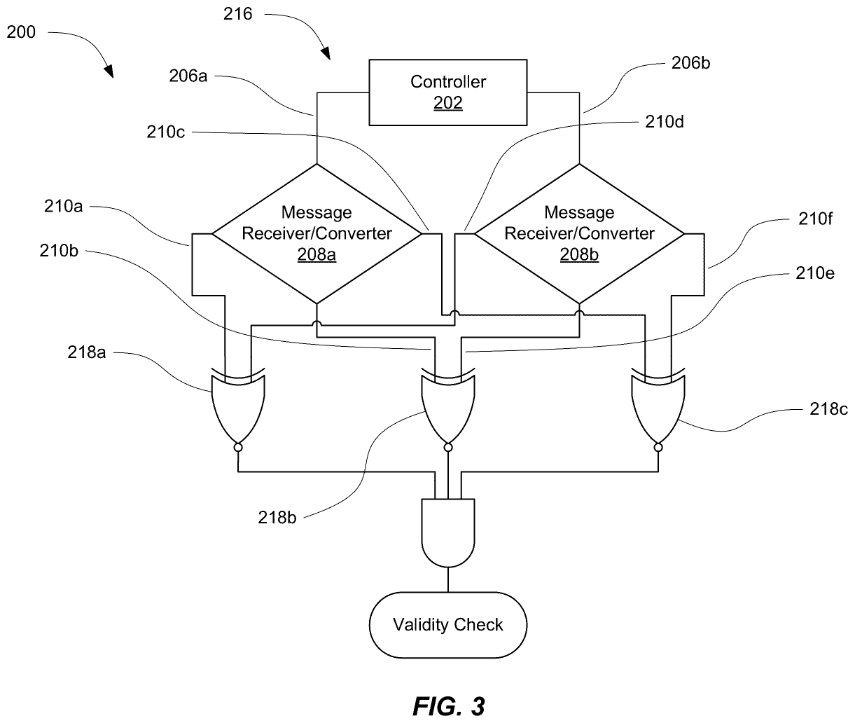

FIGS. 2 and 3 show the validation process 116 for the command signals 110 generated by the message converters 108a and 108b, respectively. FIG. 2 shows a validation circuit 116 for a power distribution control system with two switching devices 104 and 104b. The control signals 110a and 110c are compared, and if they are identical (e.g., both high or both low) then a high output is passed through the exclusive-nor logic gate 118a. Likewise the control signals 110b and 110d, both relating to the second switching device 104b, are compared and if they are identical (e.g., both high or both low) then a high output is passed through the exclusive-nor logic gate 118b. Only if the results of both comparisons is a high output, then the messages 106a and 106b are considered valid.

FIG. 3 shows another similar embodiment of a validation process 216 as part of another embodiment of a power distribution control system 200. Power distribution control system 200 is substantially similar to the control system 100, and includes 3 switching devices compared to the two devices 104a and 104b of FIGS. 1 and 2. The validation process 216 is substantially similar to that of validation process 116, with additional comparisons being made for the additional switching device. In the embodiment shown, command signals 210a and 210d, each intended for a first switching device, are compared. Similarly, command signals 210b and 210e, intended for a second switching device, are compared, while signals 210c and 210f, intended for the third switching device, are compared. In each comparison, if the respective signals are identical, a high output is passed through appropriate the exclusive-nor logic gate 218a, 218b, or 218c. Only if the result of every comparison is a high output, then the messages 206a and 206b are deemed valid. A skilled artisan will understand that in further embodiments having more than three switching devices the number of comparisons made corresponds generally to the number of switching devices, and any number of switching devices may be employed depending on the application and specific requirements of the power distribution system.

In some embodiments or applications, there may be multiple independent power distribution systems, each having their own bespoke power distribution control systems 100. Each of these multiple, independent power distribution control systems 100 may each employ their own controller 102. To protect against common mode failures in such embodiments, each controller 102 may send out completely different messages 106 such that a common mode failure between the controllers 102 does not result in erroneous, but valid, commands to all power distribution units.

Although the embodiments shown have included two or three switching devices 104, the general construction of the power distribution system 100 may be applied to embodiments having any number of switches. This can be best represented with the following Boolean algebraic expressions:

$${M}_{i} * {K}_{i} = {C}_{ij} ;$$

$${S}_{Oj} = V * {C}_{1 j} * {C}_{2 j} + \overline{V} * {S}_{Ij} ; and$$

$$V = \prod \overline{( {C}_{1 j} ( + ) {C}_{2 j} )} ;$$

wherein Mᵢ is the i^{th} message 106 from the controller 102, K, is the mapping of the message 106 to the control discretes or commands 110, Cᵢⱼ is the control discrete or command 110 from the i^{th} message converter 108a, 108b to the j^{th} switching device 104, S_{Oj} is the output state of the j^{th} switching device 104, Si is the j^{th} switching device 104 input state, V is the valid command check (V̅=V NOT), Π is the product series, and (+) is the exclusive OR operator.

Although the invention has been described with reference to the embodiments shown in the attached drawing figures, it is noted that the equivalents may be employed and substitutions made herein without departing from the scope of the invention as recited in the claims.

Having thus described various embodiments of the invention, what is claimed as new and desired to be protected by Letters Patent includes the following:

1. A method of controlling a power distribution system comprising an electronic controller connected to and in data communication with a first message converter and a second message converter, a logic circuit in data communication with the first and second message converters, and a switching device in data communication with the logic circuit, the method comprising:
sending a first message from the controller to the first message converter;
sending a second message from the controller to the second message converter, the second message being dissimilar to the first message;
generating a first command signal and outputting the first command signal from the first message converter;
generating a second command signal and outputting the second command signal from the second message converter;
comparing the first command signal to the second command signal via the logic circuit;
generating a final command signal based on the result of the comparison; and
operating the switching device via the final command signal.

2. The method of claim 1, further comprising validating the first command signal and the second command signal and generating a validation signal.

3. The method of claim 2, further comprising comparing the validation signal to the first command signal and the second command signal via the logic circuit.

4. The method of claim 2, further comprising comparing an inverse of the validation signal to an input state of the switching device via the logic circuit.

5. The method of claim 3, further comprising comparing an inverse of the validation signal to an input state of the switching device via the logic circuit.

6. A power distribution control system, comprising:
an electronic controller;
a first message converter connected to and in data communication with the controller;
a second message converter connected to and in data communication with the controller;
a switching device; and
a logic circuit in data communication with the first message converter, the second message converter, and the switching device;
wherein:
the electronic controller is configured to send a first message to the first message converter and send a second message to the second message converter, the second message being dissimilar to the first message;
the first message converter is configured to generate a first command signal upon receiving a message from the controller; and
the second message converter is configured to generate a second command signal upon receiving a message from the controller.

7. The power distribution control system of claim 6, further comprising a second logic circuit in data communication with the first and second message converters.

8. The power distribution control system of claim 7, further comprising a second switching device in data communication with the first message converter, the second message converter, and the second logic circuit.

9. The power distribution control system of claim 6, wherein the electronic controller is in data communication with an aircraft operator input device.

10. The power distribution control system of claim 6, further comprising a validation circuit in data communication with the first message converter, the second message converter, and the logic circuit.

11. The power distribution control system of claim 10, wherein the validation circuit is configured to compare the first command signal to the second command signal and generate a validation signal.

12. The power distribution control system of claim 11, wherein the logic circuit is configured to compare the validation signal to the first command signal and the second command signal.

13. The power distribution control system of claim 8, further comprising a validation circuit in data communication with the first message converter, the second message converter, the first logic circuit, and the second logic circuit;
wherein:
the first message converter is configured to generate a third command signal upon receiving a message from the controller; and
the second message converter is configured to generate a fourth command signal upon receiving a message from the controller.

14. The power distribution control system of claim 13, wherein the validation circuit is configured to:
compare the first command signal to the second command signal and generate a first validation signal;
compare the third command signal to the fourth command signal and generate a second validation signal; and
compare the first validation signal to the second validation signal and generate a final validation signal.

15. The power distribution control system of claim 14, wherein the first logic circuit is configured to:
compare the final validation signal to the first command signal and the second command signal; and
compare an inverse of the final validation signal to an input state of the first switching device; and
the second logic circuit is configured to:
compare the final validation signal to the third command signal and the fourth command signal; and
compare an inverse of the final validation signal to an input state of the second switching device.

16. A power distribution control system, comprising:
an electronic controller;
a plurality of message converters, each message converter being connected to and in data communication with the electronic controller;
a plurality of switching devices; and
a plurality of logic circuits, each logic circuit being in data communication with the plurality of message converters and the plurality of switching devices;
wherein:
the electronic controller is configured to generate a plurality of messages and send a message of said plurality of messages to each message converter of the plurality of message converters, and at least one message of the plurality of messages is dissimilar from another message of the plurality of messages; and
each message converter of the plurality of message converters is configured to generate a command signal upon receiving a message from the controller.

17. The power distribution control system of claim 16, wherein the electronic controller is in data communication with an aircraft operator input device and the plurality of messages are generated in response to an input from an aircraft operator.

18. The power distribution control system of claim 16, wherein:
each logic circuit of the plurality of logic circuits is configured to compare a first message of the plurality of messages to a second message of the plurality of messages and generate a final command signal based on the result of the comparison; and
at least one switching device of the plurality of switching devices is operable via said final command signal.

19. The power distribution control system of claim 16, further comprising a validation circuit in data communication with the plurality of logic circuits, the validation circuit being configured to:
receive a first command signal from a first message converter of the plurality of message converters and compare the first command signal to a second command signal generated by a second message converter of the plurality of message converters; and
generate a validation signal based upon the result of the comparison.

20. The power distribution control system of claim 16, further comprising a validation circuit in data communication with the plurality of logic circuits, the validation circuit being configured to:
compare each command signal generated by each message converter of the plurality of message converters to each other command signal generated by each message converter of the plurality of message converters, such that the number of comparisons performed by the validation circuit equals the number of switching devices; and
generate a validation signal.
